(19) United States
(12) Patent Application Publication
(10) Pub. No.: US 2005/0189328 A1
(43) Pub. Date: Sep. 1, 2005

(54) Laser annealing apparatus and method

(76) Inventors: I-Chang Tsao, Hsinchu (TW); Chih-Hsiung Chang, Taichung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,055

(22) Filed: Apr. 9, 2004

(30) Foreign Application Priority Data
Feb. 27, 2004 (TW) 93105042

(51) Int. Cl. B23K 26/06; H01L 21/20

(52) U.S. Cl. 219/121.65; 438/487

(57) ABSTRACT

An apparatus for laser annealing an amorphous silicon film is provided. The amorphous silicon film includes a first region and a second region not overlapped with the first region. The apparatus comprises: a laser beam source module providing a laser beam; a beam splitter, disposed on a path of the laser beam, splitting the laser beam into a first laser beam and a second laser beam; a first photomask disposed on an optical path of the first laser beam and in front of the amorphous silicon film; and a second photomask disposed an optical path of the second laser beam and in front of the amorphous silicon film; wherein the first laser beam is emitted to the first region, and the second laser beam is emitted to the amorphous silicon film in the second region after the amorphous silicon film in the first region is re-crystallized.

### CROSS REFERENCE TO RELATED APPLICATIONS

This application claims the priority benefit of Taiwan application serial no. 93105042, filed Feb. 27, 2004.

### BACKGROUND OF INVENTION

1. Field of the Invention

This invention generally relates to an apparatus and a method for laser annealing, and more particularly to an apparatus and a method for laser annealing by dividing a laser beam into two unsynchronized laser beams which pass through two photomasks with complementary patterns respectively to an amorphous silicon film.

2. Description of Related Art

As the technology advances, video products, especially digital video or image devices, are widely used in our daily life. Among the digital video or image devices, the thin film transistor liquid crystal display (TFT LCD) attracts the most attention. Among the different types of TFTs, the poly-Si TFT has electron mobility more than 200 cm²/V-sec, which is far faster than that of the α-Si TFT. Hence, the higher electron mobility can reduce the size of the TFT and increase the aperture ratio so as to enhance the brightness and reduce the power consumption of the display.

In the early stage, the process for manufacturing the poly-Si TFT was solid phase crystallization (SPC). However, because the temperature for the SPC process is 1000° C., it requires a crystal substrate with a higher melting point. Since the cost of the crystal substrate is much higher than that of the glass substrate and the size of the crystal substrate is limited to 2 or 3 inches, only small-size panels were available. Recently as the laser technology advances, an excimer laser annealing (ELA) process has been developed. The ELA process emits the laser beam to the α-Si film so that the α-Si film is melted and recrystalized to be the poly-Si film. The whole ELA process is under 600° C. Hence, the low-cost glass substrate can be used in manufacturing poly-Si TFT and in manufacturing large-size panels. It should be noted that the ELA process could use super lateral solidification (SLS) technology to form the poly-Si film with a larger grain size in order to increase the electron mobility of the poly-Si TFT. In addition, the poly-Si formed by this process is so-called low temperature poly-Silicon (LTPS).

FIG. 1 shows a conventional ELA process. Referring to FIG. 1, the conventional ELA process provides a photomask 100 above the α-Si film 50. The photomask 100 has a plurality of non-transparent regions 110. Then a pulse excimer laser beam 80a is emitted to the photomask 100. The excimer laser beam 80a in the non-transparent regions 110 will be absorbed or reflected; the excimer laser beam 80a in the other regions will pass through the photomask 100 to melt the region B of the α-Si film 50. The region A of the α-Si film 50 below the non-transparent regions 110 is used as the crystal nucleus to recrystallize the film laterally in order to form the poly-Si film. Then the photomask 100 is moved so that the non-transparent regions 110 are above the region B. Then a laser beam 80b is emitted so that the α-Si film 50 in region A can be recrystallized to form the poly-Si film.

In light of the above, the conventional ELA process requires two pulse excimer laser beams and moving the photomask to recrystallize the α-Si film in a fixed region.

FIG. 2 shows another conventional ELA process. Referring to FIG. 2, the conventional ELA process forms a first patterned mask layer 70a on the α-Si film 50. Then a pulse excimer laser beam 80a is emitted to the α-Si film so that the α-Si film 50 in the region B not covered by the first patterned mask layer 70a will be melted. The region A of the α-Si film 50 below the first patterned mask layer 70a is used as the crystal nucleus to recrystallize the film laterally in order to form the poly-Si film. Then the first patterned mask layer 70a is removed and the second patterned mask layer 70b is formed on the region B of the α-Si film 50. Then a laser beam 80b is emitted so that the α-Si film 50 in region A can be recrystallized to form the poly-Si film.

In light of the above, the conventional ELA process requires two pulse excimer laser beams and forming two patterned mask layers to recrystallize the α-Si film in a fixed region.

FIG. 3 shows still another conventional ELA process. Referring to FIG. 3, the conventional ELA process utilizes the phase interference so that the energy of the pulse excimer laser beam 80 corresponding to the α-Si film varies periodically. The energy variation of the pulse excimer laser beam 80 is shown in curve S of FIG. 3. As shown in FIG. 3, the α-Si film 50 in region B will be melted, and the region A of the α-Si film 50 is used as the crystal nucleus to re-crystallize the film laterally in order to form the poly-Si film. Then the glass substrate is moved so that the relative positions of the laser beam source and the α-Si film 50 change. Then the pulse excimer laser beam again provides periodically variant energy (not shown) to make the α-Si film 50 in region A recrystallized to be the poly-Si film.

In light of the above, the conventional ELA process requires two pulse excimer laser beams to recrystallize the α-Si film in a fixed region.

### SUMMARY OF INVENTION

An object of the present invention is to provide apparatus and method for laser annealing by using a laser beam to recrystallize the α-Si film in a certain region so as to increase the throughput of the poly-Si film.

The present invention provides an apparatus for laser annealing an amorphous silicon film, the amorphous silicon film including a first region and a second region not over-lapped with the first region, the apparatus comprising: a laser beam source module providing a laser beam; a beam splitter, disposed on a path of the laser beam, splitting the laser beam into a first laser beam and a second laser beam; a first photomask disposed on an optical path of the first laser beam and in front of the amorphous silicon film; and a second photomask disposed an optical path of the second laser beam and in front of the amorphous silicon film; wherein the first laser beam is emitted to the first region, and the second laser beam is emitted to the amorphous silicon film in the second region after the amorphous silicon film in the first region is recrystallized.

In a preferred embodiment of the present invention, the optical path length of the first laser beam to the first region is smaller than the optical path length of the second laser beam to the second region. The laser annealing apparatus further comprises a time delay device disposed on the optical path of the second laser beam. The laser beam source module can be an excimer laser beam source module, and the laser beam source module may include a plurality of laser beam sources.

In a preferred embodiment of the present invention, the first photomask includes a plurality of first stripe non-transparent regions parallel to each other, the plurality of first stripe non-transparent regions being grille-arranged, the plurality of first stripe non-transparent regions in a position corresponding to the second region; the second photomask includes a plurality of second stripe non-transparent regions parallel to each other, the plurality of second stripe non-transparent regions being grille-arranged, the plurality of second stripe non-transparent regions in a position corresponding to the first region.

In a preferred embodiment of the present invention, wherein the first photomask includes a plurality of first rectangular transparent regions, the plurality of first rectangular transparent regions being area array arranged, the plurality of first rectangular transparent regions in a position corresponding to the first region; the second photomask includes a plurality of second rectangular transparent regions, the plurality of second rectangular transparent regions being area array arranged, the plurality of second rectangular transparent regions in a position corresponding to the second region.

In a preferred embodiment of the present invention, the laser annealing apparatus further comprises a first lens module and a second lens module disposed on the optical path of the first and second laser beams respectively and in front of the first and second photomasks respectively; a projecting module disposed on the optical path of the first and second laser beams and behind the first and second photomasks; and a plurality of reflectors disposed on the optical path of the first and second laser beams.

The present invention provides a method for annealing an amorphous silicon film, the amorphous silicon film including a first region and a second region not overlapped with the first region, the method comprising: splitting a laser beam into a first laser beam and a second laser beam; emitting the first laser beam to the first region of the amorphous silicon film; and emitting the second laser beam to the second region of the amorphous silicon film, after the amorphous silicon film in the first region is recrystallized.

In a preferred embodiment of the present invention, the optical path length of the first laser beam to the first region is smaller than the optical path length of the second laser beam to the second region.

In a preferred embodiment of the present invention, the step of emitting the first laser beam to the first region of the amorphous silicon film includes: providing a first photomask on an optical path of the first laser beam so that the first laser beam passes through the first photomask to the first region; the step of emitting the second laser beam to the second region of the amorphous silicon film includes: providing a second photomask on an optical path of the second laser beam so that the second laser beam passes through the second photomask to the second region. In addition, the laser beam includes an excimer laser beam.

The above is a brief description of some deficiencies in the prior art and advantages of the present invention.

Other features, advantages and embodiments of the invention will be apparent to those skilled in the art from the following description, accompanying drawings and appended claims.

### BRIEF DESCRIPTION OF DRAWINGS

FIG. 1 shows a conventional ELA process.

FIG. 2 shows another conventional ELA process.

FIG. 3 shows still another conventional ELA process.

FIG. 4 shows the laser annealing apparatus in accordance with a preferred embodiment of the present invention.

FIGS. 5A and 5B show the top view of the first photomask and the second photomask in accordance with a preferred embodiment of the present invention.

FIGS. 6A and 6B show the top view of the first photomask and the second photomask in accordance with another preferred embodiment of the present invention.

FIG. 7 shows the laser annealing method in accordance with a preferred embodiment of the present invention.

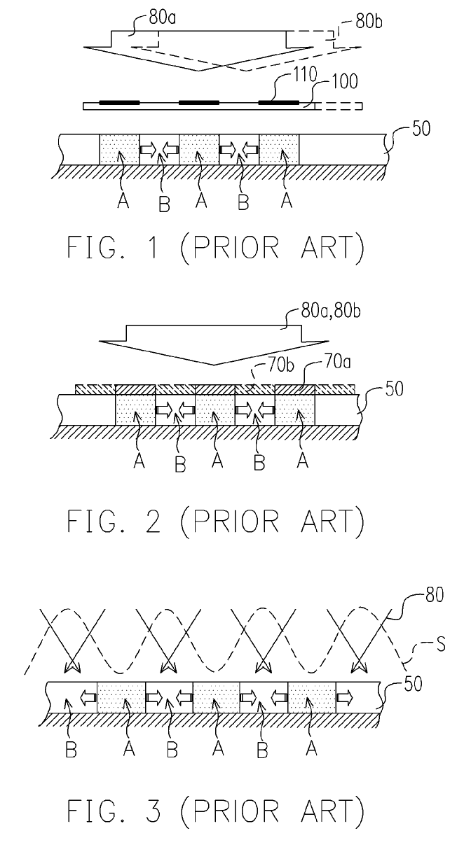

### DETAILED DESCRIPTION

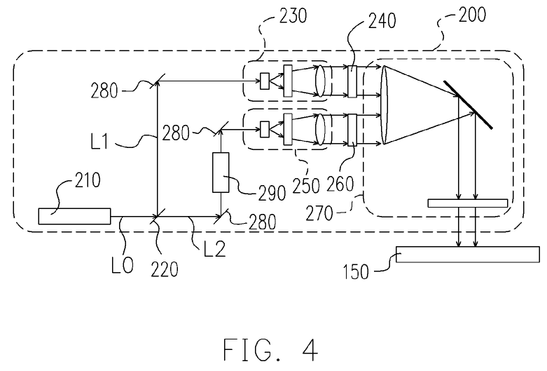

FIG. 4 shows the laser annealing apparatus in accordance with a preferred embodiment of the present invention. Referring to FIG. 4, the laser annealing apparatus 200 is for laser annealing an α-Si film 150. The laser annealing apparatus 200 includes a laser beam source module 210, a beam splitter 220, a first photomask 240, and a second photomask 260. The laser beam source module 210 provides a laser beam L0. The beam splitter 220 splits the laser beam L0 into a first laser beam L1 and a second laser beam L2. The first photomask 240 is disposed on the optical path of the first laser beam L1 and in front of the α-Si film 150. The second photomask 260 is disposed on the optical path of the second laser beam L2 and in front of the α-Si film 150.

Further, the optical path length of the first laser beam L1 to the α-Si film 150 is for example, smaller than the optical path length of the second laser beam L2 to the α-Si film 150. The laser annealing apparatus 200 further includes a time delay device 290 on the optical path of the second laser beam L2.

Further, the first laser beam L1 passes through the first photomask 240 and then is emitted to a region of the α-Si film 150. That region will not overlap with another region of the α-Si film 150 to which the second laser beam L2 passes through the second photomask 260 and then is emitted to. In addition, because of the time delay device 290, the second laser beam L2 will wait for one to several nanoseconds or milliseconds to be emitted to the α-Si film 150 after the first laser beam had been emitted to the α-Si film 150.

Referring to FIG. 4, the laser annealing apparatus 200 further includes a fist lens module 230, a second lens module 250, a projecting module 270, and a plurality of reflectors 280. The first lens module 230 is disposed on the optical path of the first laser beam L1 and in front of the first photomask 240 so that the first laser beam L1 can be uniformly and perpendicularly emitted into the first photomask 240. The second lens module 250 is disposed on the optical path of the second laser beam L2 and in front of the second photomask 260 so that the second laser beam L2 can be uniformly and perpendicularly emitted into the second photomask 260. The projecting module 270 is disposed on the optical paths of the first and second laser beams L1 and L2 and behind the first and second photomasks 240 and 260. The projecting module 270 can adjust the optical paths of the first and second laser beams L1 and L2 so that the first and second laser beams L1 and L2 can be emitted to the same region of the α-Si film 150. The reflectors 280 are disposed on the optical paths of the first and second laser beams L1 and L2. The reflectors 280 can change the optical paths of the first and second laser beams L1 and L2 for the optical design and space arrangement of the laser annealing apparatus 200.

Further, the laser beam source module 210 for example is an excimer laser beam source module. The laser beam source module 210 for example can be a plurality of laser beam source modules. Because a single laser beam source can only provide a fixed energy. By using a plurality of laser beam source modules, the energy density of the laser beam is high enough to process a larger region at a time in order to increase the throughput.

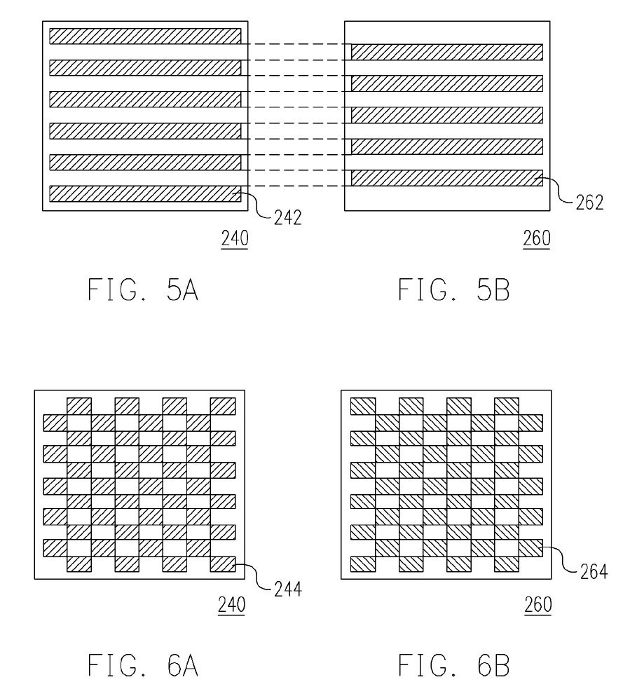

FIGS. 5A and 5B show the top view of the first photomask and the second photomask in accordance with a preferred embodiment of the present invention. Referring to FIGS. 5A and 5B, the first photomask 240 has a plurality of first stripe non-transparent regions 242 parallel to each other. The first stripe non-transparent regions 242 are grille-arranged. The second photomask 260 has a plurality of second stripe non-transparent regions 262 parallel to each other. The second stripe non-transparent regions 262 are grille-arranged. The relative position of the second stripe non-transparent regions 262 does not overlap with that of the first stripe non-transparent regions 242.

FIGS. 6A and 6B show the top view of the first photomask and the second photomask in accordance with another preferred embodiment of the present invention. Referring to FIGS. 6A and 6B, the first photomask 240 has a plurality of first rectangular transparent regions 244. The first rectangular transparent regions 244 are area array arranged, and the adjacent first rectangular transparent regions 244 in the same row are not aligned. The second photomask 260 has a plurality of second rectangular transparent regions 264. The second rectangular transparent regions 264 are area arrayarranged, and the adjacent second rectangular transparent regions 264 in the same row are not aligned. The relative position of the second rectangular transparent regions 264 does not overlap with that of the first rectangular transparent regions 244.

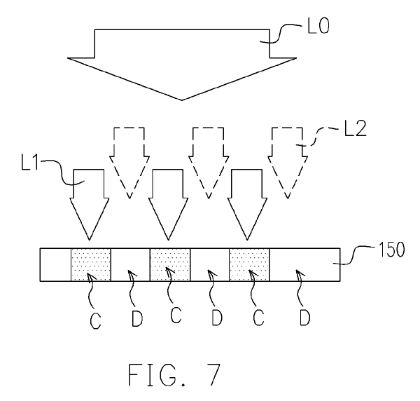

FIG. 7 shows the laser annealing method in accordance with a preferred embodiment of the present invention. Referring to FIG. 7, this laser annealing method is for annealing an α-Si film 150. The α-Si film 150 includes a first region C and a second region D not overlapped with the first region C. This laser annealing method in accordance with a preferred embodiment of the present invention comprises: splitting the laser beam L0 into the first laser beam L1 and the second laser beam L2; emitting the first laser beam L1 to the first region C of α-Si film 150; and emitting the second laser beam L2 to the second region D of the α-Si film 150, after the α-Si film 150 in the first region C is recrystallized.

Referring to FIGS. 4 and 7, the optical path length of the first laser beam L1 to the first region C is smaller than the optical path length of the second laser beam L2 to the second region D. In addition, the step of emitting the first laser beam L1 to the first region C of the α-Si film 150 includes: providing a first photomask 240 on the optical path of the first laser beam L1 so that the first laser beam L1 passes through the first photomask 240 to the first region C. The step of emitting the second laser beam L2 to the second region D of the α-Si film 150 includes: providing a second photomask 260 on the optical path of the second laser beam L2 so that the second laser beam L2 passes through the second photomask 260 to the second region D. It should be noted that the present invention is limited to use photomasks for the laser beams L1 and L2 to be emitted in a predetermined region. Other adequate methods or devices for blocking laser beams also fall within the scope of the invention. In addition, the pattern of the second photomask 260 does not overlap with that of the first photomask 240. In a preferred embodiment of the present invention, the laser beam L0 is an excimer laser beam.

It should be noted that in a preferred embodiment of the present invention, the above laser annealing method is, but not limited to, suitable to be processed in the above laser annealing apparatus.

In light of the above, the laser annealing apparatus and method of the present invention have at least the following advantages.
1. It only requires a single pulse laser beam to recrystallize the α-Si film in a certain region to the poly-Si film at a time so as to reduce the process time and increase the throughput.
2. It is unnecessary to move the photomask in order to recrystalize the α-Si film in a certain region to the poly-Si film at a time so as to reduce the process time and increase the throughput.
3. The laser annealing method of the present invention is easier to combine more laser beam sources into the laser beam source module in order to use a single pulse laser beam to process a larger area at a time.

The above description provides a full and complete description of the preferred embodiments of the present invention. Those may make various modifications, alternate construction, and equivalent skilled in the art without changing the scope or spirit of the invention. Accordingly, the above description and illustrations should not be constructed as limiting the scope of the invention, which is defined by the following claims.

1. An apparatus for laser annealing an amorphous silicon film, said amorphous silicon film including a first region and a second region not overlapped with said first region, said apparatus comprising:
a laser beam source module providing a laser beam;
a beam splitter, disposed on a path of said laser beam, splitting said laser beam into a first laser beam and a second laser beam;
a first photomask disposed on an optical path of said first laser beam and in front of said amorphous silicon film; and
a second photomask disposed an optical path of said second laser beam and in front of said amorphous silicon film;
wherein said first laser beam is emitted to said first region, and said second laser beam is emitted to said amorphous silicon film in said second region after said amorphous silicon film in said first region is recrystallized.

2. The apparatus of claim 1, wherein an optical path length of said first laser beam to said first region is smaller than an optical path length of said second laser beam to said second region.

3. The apparatus of claim 1, further comprising a time delay device disposed on said optical path of said second laser beam.

4. The apparatus of claim 1, wherein said laser beam source module includes an excimer laser beam source module.

5. The apparatus of claim 1, wherein said laser beam source module includes a plurality of laser beam sources.

6. The apparatus of claim 1, wherein said first photomask includes a plurality of first stripe non-transparent regions parallel to each other, said plurality of first stripe non-transparent regions being grille-arranged, said plurality of first stripe non-transparent regions in a position corresponding to said second region.

7. The apparatus of claim 1, wherein said second photomask includes a plurality of second stripe non-transparent regions parallel to each other, said plurality of second stripe non-transparent regions being grille-arranged, said plurality of second stripe non-transparent regions in a position corresponding to said first region.

8. The apparatus of claim 1, wherein said first photomask includes a plurality of first rectangular transparent regions, said plurality of first rectangular transparent regions being area array arranged, said plurality of first rectangular transparent regions in a position corresponding to said first region.

9. The apparatus of claim 1, wherein said second photomask includes a plurality of second rectangular transparent regions, said plurality of second rectangular transparent regions being area array arranged, said plurality of second rectangular transparent regions in a position corresponding to said second region.

10. The apparatus of claim 1, further comprising a first lens module and a second lens module disposed on said optical path of said first and second laser beams respectively and in front of said first and second photomasks respectively.

11. The apparatus of claim 1, further comprising a projecting module disposed on said optical path of said first and second laser beams and behind said first and second photomasks.

12. The apparatus of claim 1, further comprising a plurality of reflectors disposed on said optical path of said first and second laser beams.

13. A method for annealing an amorphous silicon film, said amorphous silicon film including a first region and a second region not overlapped with said first region, said method comprising:
splitting a laser beam into a first laser beam and a second laser beam;
emitting said first laser beam to said first region of said amorphous silicon film; and
emitting said second laser beam to said second region of said amorphous silicon film, after said amorphous silicon film in said first region is recrystallized.

14. The method of claim 13, wherein an optical path length of said first laser beam to said first region is smaller than an optical path length of said second laser beam to said second region.

15. The method of claim 13, wherein said step of emitting said first laser beam to said first region of said amorphous silicon film includes: providing a first photomask on an optical path of said first laser beam so that said first laser beam passes through said first photomask to said first region.

16. The method of claim 13, wherein said step of emitting said second laser beam to said second region of said amorphous silicon film includes: providing a secondphotomask on an optical path of said second laser beam so that said second laser beam passes through said second photomask to said second region.

17. The method of claim 13, wherein said laser beam includes an excimer laser beam.
